(19) United States
(12) Patent Application Publication
(10) Pub. No.: US 2016/0042985 A1
(43) Pub. Date: Feb. 11, 2016

(54) SUBSTRATE PROCESSING APPARATUS

(71) Applicant: KABUSHIKI KAISHA TOSHIBA, Tokyo (JP)

(72) Inventor: NOBUHIDE YAMADA, Nagoya Aichi (JP)

(21) Appl. No.: 14/630,424

(22) Filed: Feb. 24, 2015

Related U.S. Application Data
(60) Provisional application No. 62/034,445, filed on Aug. 7, 2014.

(51) Int. Cl. H01L 21/67; H01L 21/66; G01N 21/95; H01L 21/677

(52) U.S. Cl. CPC H01L 21/67288; H01L 21/67742; H01L 22/12; H01L 21/67196; H01L 21/67201; G01N 21/9501

(57) ABSTRACT

A substrate processing apparatus includes a mounting unit on which a substrate is mounted, a light generation and detection unit that forms an optical path parallel to a surface of the substrate at a location separated from the surface of the substrate by a predetermined distance and is capable of detecting shielding of the optical path, and a control unit that controls movement of at least one of the mounting unit and the optical path to control relative movement between the optical path and the substrate in a state where parallelism between the optical path and the surface of the substrate is maintained.

### CROSS-REFERENCE TO RELATED APPLICATION

This application is based upon and claims the benefit of priority from U.S. Provisional Patent Application No. 62/034,445, filed Aug. 7, 2014, the entire contents of which are incorporated herein by reference.

### FIELD

Embodiments described herein relate to a substrate processing apparatus.

### BACKGROUND

During the process of manufacturing devices, such as semiconductor devices and liquid crystal panels, on a substrate, thin film layers formed on the substrate may peel off as a result of improper thin film processing conditions, inappropriate substrate conditions, or the like. In such a case, when further processing of the substrate proceeds after the occurrence of film peeling, non-peeling substrates and other devices within a clean room may be contaminated by the peeled film when it comes off of the substrate. Thus, it is important to detect film peeling on the substrate.

Hitherto, a method of detecting abnormalities on substrates undergoing thin film processing, such as film peeling occurring on a substrate, includes a method of capturing an image of the surface of the substrate using a camera and performing a determination of whether film peeling is occurring, or has occurred, by image recognition based on the captured image. However, the surface of the substrate is seen in different ways depending on pattern (s) formed on or in the one or more film layers on the substrate, and thus conditions for the determination become complicated. For this reason, when image recognition using the camera is performed, there is a problem in that it takes time and effort to set the conditions for the determination or it is difficult to perform the determination.

### BRIEF DESCRIPTION OF THE DRAWINGS

FIG. 1 is a cross-sectional plan view illustrating an example of a schematic configuration of a substrate processing apparatus according to a first embodiment.

FIG. 2 is a longitudinal sectional side view illustrating an example of a schematic configuration of the substrate processing apparatus according to the first embodiment.

FIG. 3 is a diagram illustrating an example of a positional relationship between a mounting unit and a light detection unit according to the first embodiment.

FIG. 4 is a diagram illustrating an example of a schematic electrical configuration of the substrate processing apparatus according to the first embodiment.

FIG. 5 is a diagram illustrating an example of control contents using a control unit according to the first embodiment.

FIG. 6 is a cross-sectional plan view illustrating an example of a schematic configuration of a substrate processing apparatus according to a second embodiment.

FIG. 7 is a longitudinal sectional side view illustrating an example of a schematic configuration of the substrate processing apparatus according to the second embodiment.

### DETAILED DESCRIPTION

A substrate processing apparatus according to this embodiment includes a mounting unit on which a substrate is mounted, a light generating and detection unit that forms an optical path parallel to a surface of the substrate at a location separated from the surface of the substrate by a predetermined distance and is capable of detecting shielding of the optical path, and a control unit that controls movement of at least one of the mounting unit and the optical path to control relative movement between the optical path and the substrate in a state where parallelism between the optical path and the surface of the substrate is maintained.

### First Embodiment

[Configuration]

Hereinafter, a substrate processing apparatus according to a first embodiment which is applied to an apparatus for manufacturing a semiconductor device will be described with reference to the accompanying drawings. Meanwhile, the substrate processing apparatus is not limited to the apparatus for manufacturing a semiconductor device, and may also be applied to, for example, an apparatus for manufacturing a liquid crystal panel. In the following description, components having the same function and configuration will be denoted by the same reference numerals and signs. The drawings are schematically illustrated, and dimensional relationships, ratios, and the like of an apparatus and a substrate do not necessarily coincide with an actual apparatus and substrate.

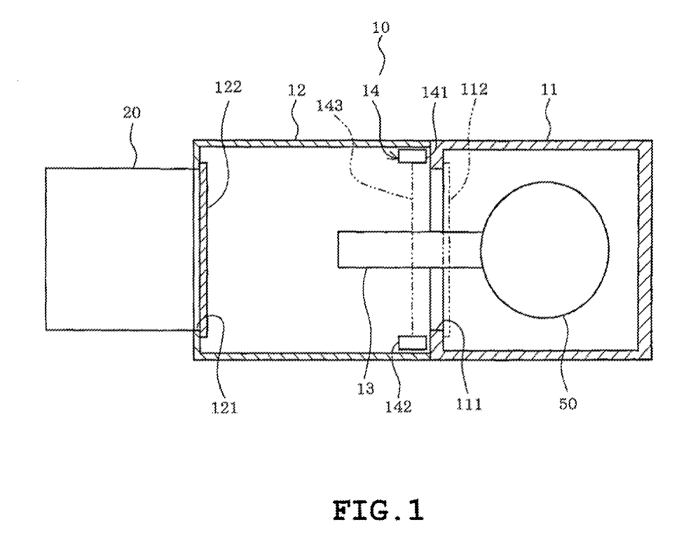

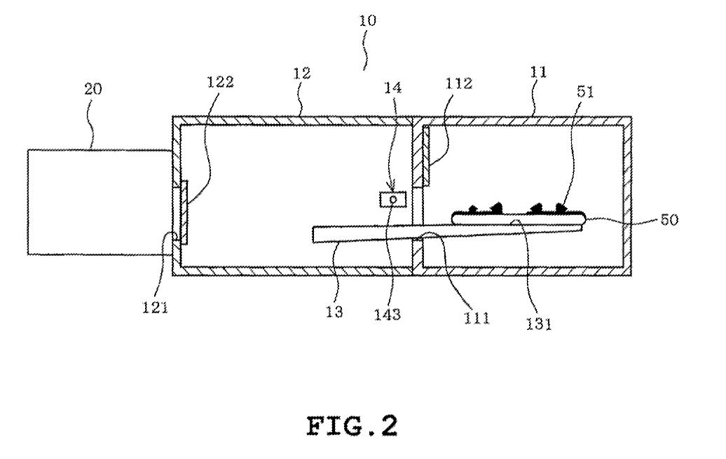

A substrate processing apparatus 10 illustrated in FIGS. 1 and 2 is an apparatus that performs processing such as film formation, dry etching, polishing, cleaning, or inspection on a substrate 50 such as, for example, a silicon wafer or a glass substrate. The substrate processing apparatus 10 includes a processing chamber 11 and a front chamber 12. The processing chamber 11 is a space in which the substrate 50 is accommodated at the time of performing processing on the substrate 50. The processing chamber 11 may be referred to as a treatment chamber. The front chamber 12 is configured as a transfer chamber having space therein for transferring the substrate 50 between a transport container 20 and the processing chamber 11. The front chamber 12 may be referred to as a transport chamber.

The transport container 20 is an example of a container in which the substrate 50 is accommodated. The transport container 20 is, for example, a front opened unified pod (FOUP) and can accommodate the plurality of substrates 50. The substrate 50 is transported between an apparatus for performing a previous process and the substrate processing apparatus 10 and between the substrate processing apparatus 10 and an apparatus for performing a subsequent process in a state where the substrate 50 is accommodated in the transport container 20. The transport container 20 includes a lid not illustrated in the drawing in a state where the lid, the inside of the transport container 20 is in a sealed state. Thus, the substrate 50 is transported between process stations in a state where the substrate is shielded within the transport container 20 from the conditions exterior thereto, such as the air in the ambient environment.

The front chamber 12 is configured to be capable of communicating with the exterior thereof through a communication portion 121. The front chamber 12 includes a front chamber door 122 which is capable of opening and closing the communication portion 121. When the front chamber door 122 is closed, the communication portion 121 is closed. In this state, outside air is prevented from flowing into the front chamber 12 through the communication portion 121. When the front chamber door 122 is opened, the communication portion 121 is opened. The substrate 50 moves between the transport container 20 and the front chamber 12 through the communication portion 121 in a state where the lid of the transport container 20 and the front chamber door 122 are opened and the container is mounted to the front chamber.

The processing chamber 11 and the front chamber 12 are configured to communicate with each other through a communication portion 111. The processing chamber 11 includes a processing chamber door 112 which is capable of opening and closing the communication portion 111. The processing chamber door 112 is provided between the processing chamber 11 and the front chamber 12. In a state where the processing chamber door 112 is closed, the processing chamber 11 becomes a sealed space. Processing of the substrate 50 is performed in a state where the processing chamber 11 is sealed by closing the processing chamber door 112. In a state where the processing chamber door 112 is opened, the processing chamber 11 and the front chamber 12 are set to be in a state where the chambers communicate with each other through the communication portion 111. The substrate 50 moves between the processing chamber 11 and the front chamber 12 through the communication portion 111 in a state where the processing chamber door 112 is opened.

The substrate processing apparatus 10 includes a movement mechanism 13. The movement mechanism 13 is, for example, a robot arm provided in the front chamber 12. The movement mechanism 13 is used to transfer the substrate 50 between the transport container 20 and the front chamber 12 and between the front chamber 12 and the processing chamber 11. The movement mechanism 13 includes a mounting unit 131, which is capable of mounting the substrate 50, at a tip portion of the arm. The mounting unit 131 can support the substrate 50 so that the surface of the substrate 50 is held in a horizontal orientation with a high degree of accuracy. In the processing chamber 11, the upwardly facing surface of the substrate 50 is processed. The mounting unit 131 of the movement mechanism 13 is configured to be movable between the transport container 20 and the front chamber 12 and between the front chamber 12 and the processing chamber 11.

The substrate processing apparatus 10 includes a light projecting and detection unit 14. For example, the light detection unit 14 is provided in the vicinity of the communication portion 111 within the front chamber 12. The light projecting and detection unit 14 is, for example, a transmissive photoelectric sensor and includes a light projection unit 141 and a light receiving unit 142. The light projection unit 141 projects alight beam. The light receiving unit 142 receives the light beam projected from the light projection unit 141. Thus, an optical path 143 of the light beam extends between the light projection unit 141 and the light receiving unit 142. When the optical path 143 is shielded or blocked by any object, the light detection unit 14 can detect the shielding or blocking of the optical path 143. Thus, when a substrate having a layer thereon which has at least partially peeled off the surface of the substrate, the optical path 143 is shielded by the peeled portion of the film extending from the surface of the substrate 50, so-called particles 51 such as dust on the upper surface of the substrate, or the substrate itself where the substrate is bent or warped.

A light emitting diode, a laser, or the like is appropriately selected as a light source of the light projection unit 141 in accordance with a required resolution of the beam in the in the optical path 143 and at the light receiving unit 142. In addition, the light projecting and detection unit 14 is not limited to a transmissive type in which the light projection unit 141 and the light receiving unit 142 are spaced from each other. The light detection unit 14 may be, for example, a regression reflection type or a diffusion reflection type in which the light projection unit and the light receiving unit are integrally formed, and the light path extends across, is reflected, and again crosses the substrate 50.

The optical path 143 of the light detection unit 14 is located above the substrate 50 and is provided to be parallel to the surface of the substrate 50. In this case, the mounting unit 131 is movable, and thus the relative position of the optical path 143 to the substrate 50 can be relatively moved in a state where parallelism between the optical path 143 and the surface of the substrate 50 is maintained. A distance between the surface of the substrate 50 and the optical path 143, that is, the height position of the optical path 143 is set to be lower than an allowable height of any peeled film layer and/or undesirable particles 51 contaminating the substrate 50 surface. For example, when the acceptable height (i.e., the acceptable average particle size or diameter) of the particles 51 from the surface of the substrate 50 is in a range of several tens of μm to several hundreds of μm, a distance between the surface of the substrate 50 and the optical path 143 is set to be in a range of several tens of μm to several hundreds of μm.

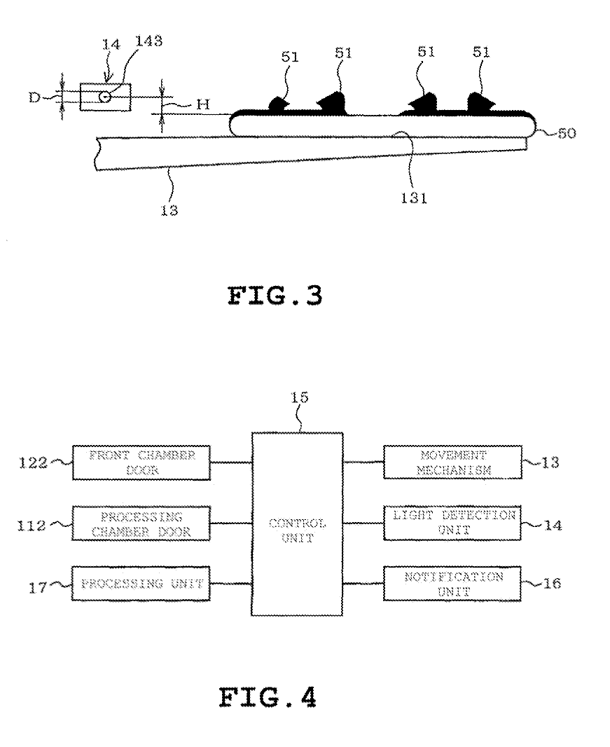

In this embodiment, as illustrated in FIG. 3, the distance (gap) between the optical path 143 and the surface of the substrate 50 is set to equal to or greater than 10 [μm]. In other words, the optical path 143 is set to pass above the surface of the substrate 50 which is separated therefrom by a distance of equal to or greater than 10 μm. In this case, the surface may be the surface of the substrate 50 or may be an upper surface of a film formed in the substrate 50.

In addition, a spot diameter D of the optical path 143, i.e., the cross section of the beam, is set in a range of several tens of [μm] to several hundreds of [μm]. In this embodiment, the spot diameter D of the optical path 143 is set to equal to or less than 100 [μm]. That is, the spot diameter D and a distance H between the surface of the substrate 50 and the center of the spot diameter D of the optical path 143 are set to satisfy the following relations Expression 1 and Expression 2. Meanwhile, the spot diameter D and the distance H are appropriately changed in accordance with an allowable size of the particles 51, and the like.

D≦100 [μm] (Expression 1)

H−D/2≧10 [μm] (Expression 2)

As illustrated in FIG. 4, the substrate processing apparatus 10 includes a control unit 15. The control unit 15 is configured with a computer, not illustrated in the drawing, which includes a CPU, a RAM, a ROM, and the like and controls the entirety of the substrate processing apparatus 10. That is, the control unit 15 controls the opening and closing of the processing chamber door 112, the opening and closing of the front chamber door 122, the positioning of the movement mechanism 13, the operation of the light detection unit 14, and the like. In addition, for example, the control unit 15 may be capable of communicating with the apparatuses performing the previous and subsequent processes on the substrate 50, a transport device (not shown) that transports the transport container 20, and the like.

As illustrated schematically in FIG. 4, the substrate processing apparatus 10 includes a notification unit 16 and a processing unit 17. The notification unit 16 is an example of a notification device and/or software that provides a notification when shielding (blocking) of the optical path 143 is detected by the light detection unit 14. The notification unit 16 is, for example, a buzzer, a speaker, or a display and is used to issue a notification using a sound, a light signal, or an image. The processing unit 17 is, for example, a film forming device, a polishing device, a cleaning device, or an inspection device and is used to perform processing on the substrate 50 accommodated in the processing chamber 11, i.e., the processing chamber can be configured as a film forming device, a polishing device, a cleaning device, or an inspection device. A specific configuration of the processing unit 17 is appropriately changed in accordance with the details of the processing thereon or therein.

[Control Contents]

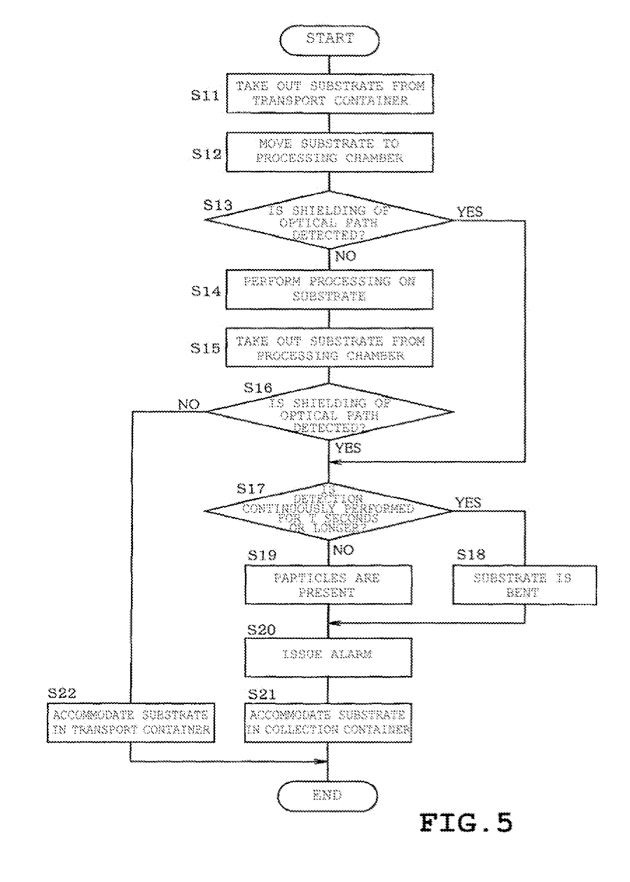

Next, control using the control unit 15 will be described with reference to FIG. 5.

The substrate 50 processed in the previous process is transported to the substrate processing apparatus 10 by a transport device (not shown) in the transport container 20. Thereafter, the lid of the transport container 20 and the front chamber door 122 of the front chamber 12 are opened. Thus, the substrate 50 is positioned to be movable between the transport container 20 and the front chamber 12 through the communication portion 121.

In a state where the substrate 50 is positioned to be movable between the transport container 20 and the front chamber 12, the control illustrated in FIG. 5 is performed. When the control of FIG. 5 is initiated or begun (start), in step S11, the control unit 15 moves the mounting unit 131 of the movement mechanism 13 to remove, from the transport container 20, a substrate 50 to be processed.

Next, in step S12, the control unit 15 opens the processing chamber door 112, and the mounting unit 131 is moved from the front chamber 12 to locate the substrate 50 in the processing chamber 11. At this time, the substrate 50 moves in a state where parallelism between the surface of the substrate 50 and the optical path 143 is maintained. That is, the optical path 143 crosses above the entire surface of the substrate 50. At this time, when particles 51 are present or another abnormality occurs in the surface of the substrate 50 such as the bending of the substrate 50 or peeling or blistering of a film layer thereon, the optical path 143 is shielded or blocked by the particles 51 or the bending.

In step S13, the control unit 15 determines whether or not the optical path 143 is shielded (blocked) during the movement of the substrate 50. When the optical path 143 is shielded during the movement of the substrate 50 during loading of the substrate (YES in step S13) into the processing chamber 11, the control unit 15 determines that the surface of the substrate 50 is in an abnormal state and proceeds to step S17. On the other hand, when the optical path 143 is not shielded during the movement of the substrate 50 into the processing chamber 11 (NO in step S13), the control unit 15 determines that the surface of the substrate 50 is in a normal (i.e., no particles of a preselected size or peeling, blistering are detected, and no warping of the substrate is detected) state and proceeds to step S14.

In step S14, the control unit 15 moves the mounting unit 131 from the front chamber 12 to the processing chamber 11 to load the substrate 50 into the processing chamber 11. The mounting unit retracts from the processing chamber 11, and control unit 15 closes the processing chamber door 112, and actuates the processing unit 17 to perform selected processing of the substrate 50. When the processing of the substrate stops, in step S15, the control unit 15 opens the processing chamber door 112, actuates the mounting unit 131 to take the substrate 50 from the processing chamber 11 and move it into the front chamber 12.

Similarly to step S13, when the substrate 50 is taken out from the processing chamber 11, the control unit 15 determines whether or not the optical path 143 is shielded (blocked) during the movement of the substrate 50 thereunder or therepast. When the optical path 143 is not shielded during the removal of the substrate 50 (NO in step S16), the control unit 15 determines that the surface of the substrate 50 is in a normal state and proceeds to step S22. Thereafter, in step S22, the control unit 15 moves the substrate 50 into the transport container 20. Then, control of the substrate processing apparatus 10 is terminated, or the loading of another substrate is begun (end).

On the other hand, when the optical path 143 is shielded during the removal of the substrate 50 from the processing chamber (YES in step S16), the control unit 15 determines that the surface of the substrate 50 is in an abnormal state and proceeds to step S17. In step S17, the control unit 15 determines whether or not the shielding of the optical path 143 is continuously detected for t seconds or longer as the substrate moves past the optical path.

That is, in a case where the substrate 50 is bent or warped, there is a possibility of the optical path 143 being shielded during the movement of the substrate 50 past the optical path 143 due to the bent or warped status of the substrate. The size of the particles 51 or delaminations (peels) of the film layer on the surface of the substrate 50 is sufficiently smaller than the diameter of the substrate 50. Therefore, a time period during which the optical path 143 is shielded due to the presence of particles 51 or peeled or blistered film layers is significantly shorter than a time period during which the optical path 143 is shielded due to the bending or warping of the substrate 50. As a result, the control unit 15 is able to determine whether the shielding of the optical path 143 is caused by particles 51 or by bending or warping of the substrate 50 by tracking or measuring the length or period of time during which the optical path 143 is shielded or blocked by the substrate 50.

That is, when the time period during which the optical path 143 is shielded is t seconds or longer as a threshold value (YES in step S17), the control unit 15 determines that the substrate 50 is bent or warped (step S18). On the other hand, when the time period during which the optical path 143 is shielded is less than t seconds (NO in step S17), the control unit 15 determines that particles 51 or a peeled film layer are present on the surface of the substrate 50 (step S19).

When the movement speed of the substrate 50, that is, a relative speed between the substrate 50 and the optical path 143 is set to V [mm/s] and a diameter of the substrate 50 is set to L [mm], the t seconds as a threshold value can be set, for example, by the following Expression 3.

t=(L/V)×α [s] (Expression 3)

In this case, α denotes a coefficient representing the size of the bending and has a value in a range of 0 to 1. For example, when α=⅓ is selected and the distance between the closest position of the optical path 143 to the surface of the substrate 50 and the surface of the substrate 50 is set as 10 [μm], and the time period over which the optical path 143 is shielded or blocked is t seconds or longer, bending of the substrate of 10 μm or greater occurs over one-third or more of the substrate 50 having the diameter L.

In step S18 and step S19, when the bending of the substrate 50 or the presence of the particles 51 on the surface of the substrate 50 is detected, in step S20, the control unit 15 drives the notification unit 16 to issue an alarm. The alarm is used to notify a manager, or other person responsible for operation of the substrate processing apparatus 10, of the occurrence of an abnormality on or of the substrate 50. Contents of the alarm may include not only the presence of abnormality on the surface of the substrate 50 but also, for example, contents capable of identifying whether the abnormality is caused by the presence of one or more particles 51 or of a bent or warped substrate 50. In addition, the alarm is not limited to using a device included in the substrate processing apparatus 10, and may be issued using a device, such as a monitoring terminal and GUI located elsewhere than the substrate processing apparatus 10 such as, for example, a personal computer or a mobile phone which is used by manager or other person responsible for operation of the substrate processing apparatus 10.

When it is determined that the substrate 50 has abnormality, the control unit 15 controls the movement of the mounting unit 131 so that the substrate 50 having an abnormality is not placed back into the transport container 20. That is, in step S21, the control unit 15 moves the mounting unit 131 to thereby allow the substrate 50, for which particles 51 or bending is detected, to be accommodated in a collection container not illustrated in the drawing. For example, the collection container and the transport container 20 have the same configuration, but the objects thereof are sorted between good and defective substrates. That is, the collection container is used to collect defective substrates. The substrate 50 placed in the collection container is not transported to the subsequent process and is collected as a defective. Thereafter, the control unit 15 terminates control, or the loading of another substrate is begun (end). Alternatively, in step S21, the substrate processing apparatus 10 may be stopped, and a manager or other person responsible for operation of the substrate processing apparatus 10 may be entrusted with further processing of the substrate 50.

According to the above-described embodiment, the light detection unit 14 of the substrate processing apparatus 10 forms an optical path 143 which is parallel to the surface of the substrate 50, and spaced from the surface of the substrate 50 by a predetermined (preselected) distance. The light detection unit 14 can detect the shielding or blocking of the optical path 143. In addition, the control unit 15 controls the movement of at least one of the mounting unit 131 and the optical path 143 by relatively moving the optical path 143 and the substrate 50 such that parallelism between the optical path 143 and the surface of the substrate 50 is maintained.

Accordingly, when the mounting unit 131 is moved while a substrate 50 is mounted on the mounting unit 131, the control unit 15 detects whether or not the optical path 143 is shielded or blocked in order to detect the presence of one or more particles 51 which may be present on the surface of the substrate 50. Therefore, the substrate processing apparatus 10 is not required to perform complicated determination such as image recognition by using a complicated device such as, for example, a camera, in order to detect particles 51 on the substrate 50. For this reason, a configuration and setting of the device for detecting particles 51 is simplified. Thus, since appropriate setting can be easily performed, it is possible to easily detect the particles 51 as compared with, for example, image recognition. In addition, the man-hours required for the setting of the substrate processing apparatus 10 are reduced. As a result, it is also possible to achieve an improvement in the productivity of the processing apparatus 10.

When the time period during which the optical path 143 is shielded is continued for t seconds or longer, the control unit 15 determines that the substrate 50 is bent or warped. When the time period is less than t seconds, the control unit determines that particles 51 are present on the substrate 50. Accordingly, it is possible to detect bending or warping of the substrate 50 by using the same hardware and software configuration as is used for detecting particles 51. Thus, it is possible to detect both particles 51 or peeling, and bending or warping of the substrate 50, with the same simple configuration.

The control unit 15 can detect particles 51 or the presence of a peeled or blistered film layer on the substrate 50, or a bent or warped substrate by using the light detection unit 14 during movement of the substrate 50 between the processing chamber 11 and the front chamber 12. Therefore, it is not necessary to dedicate additional time in order to detect particle 51 or peeling or substrate bending or warping. For this reason, it is possible to reduce time required for processing and checking the substrate. As a result, it is possible to achieve an improvement in the production efficiency of processing substrates in the processing apparatus 10.

The substrate processing apparatus 10 can move the substrate 50 and the optical path 143 of the light detection unit 14 relative to each other, and the optical path 143 can cross above the entire surface of the substrate 50. Accordingly, the substrate processing apparatus 10 can perform inspection on the entirety of the substrate 50 without by using one optical path 143. Thus, it is possible to more reliably inspect a surface state of the substrate 50.

The light projection unit 141 and the light receiving unit 142 of the light detection unit 14 are provided within the front chamber 12 not within the processing chamber 11. Accordingly, the light projection unit 141 and the light receiving unit 142 are not contaminated by exposure to processes performed within the processing chamber 11. Consequently, it is possible to maintain the detection accuracy of the light detection unit 14 for a long period of time. That is, it is possible to reduce the number of times maintenance and the like of the light detection unit 14 must be undertaken. Therefore, the number of times use of the substrate processing apparatus 10 must be interrupted for maintenance and the like of the light detection unit 14 is reduced. As a result, it is possible to achieve an improvement in the productivity of the substrate processing apparatus 10.

The substrate processing apparatus 10 includes a notification unit 16 that provides a notification when the light detection unit 14 detects the shielding or blocking of the optical path 143. Accordingly, when an abnormality such as the presence of the particles 51 or peeling or blistered film on the surface of the substrate 50 occurs, a manager can be reliably informed of the occurrence of the abnormality. As a result, the manager or other person responsible for the operation of the substrate processing apparatus 10 is reliably informed of the presence of defects and can thus suppress the outflow of defective substrates from the substrate processing apparatus to a further processing apparatus, and the like.

When the light detection unit 14 detects shielding or blocking of the optical path 143, the control unit 15 controls the movement of the mounting unit 131 so that a substrate 50 having an abnormality or defect is not returned to the transport container 20. Accordingly, a normal substrate 50 on which the particles 51 and the like are not present, generated and a substrate 50 on which abnormality or defect such as a particle (s) 51 is present are prevented from being commingled within the transport container 20. As a result, it is possible to ensure that a normal substrate 50 is not contaminated by a substrate 50 having an abnormality or defect.

### Second Embodiment

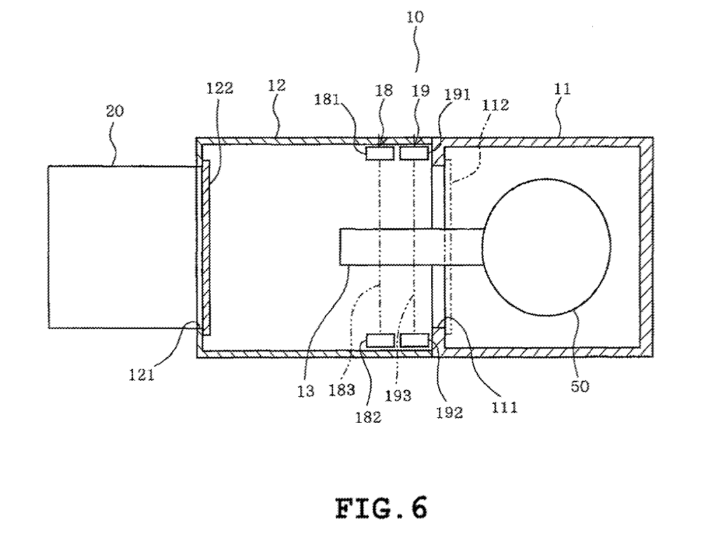

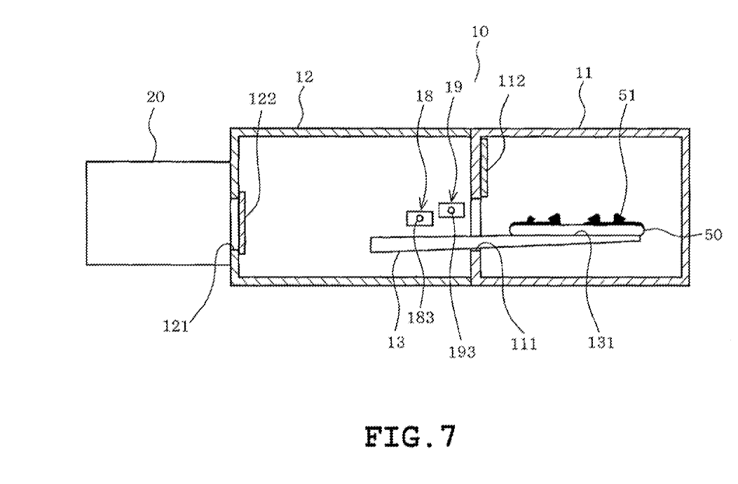

Next, a second embodiment will be described with reference to FIGS. 6 and 7.

A substrate processing apparatus 10 according to the second embodiment includes a plurality of, for example, two light detection units 18 and 19. In the following description, when the light detection units 18 and 19 are individually described, the light detection units will be referred to as the first light detection unit 18 and the second light detection unit 19, respectively. The configuration of each of the light detection units 18 and 19 is the same as the configuration of the light detection unit 14 of the first embodiment. In this case, the first light detection unit 18 includes a light projection unit 181, a light receiving unit 182, and an optical path 183. The second light detection unit 19 includes a light projection unit 191, a light receiving unit 192, and an optical path 193. The locations of the optical paths 183 and 193 of the first light detection unit 18 and the second light detection unit 19 are different from each other.

That is, in a silicon wafer having a diameter of, for example, 300 [mm], a permissible value of the amount of bending is usually set to equal to or less than 200 [μm]. In order to discriminate an acceptably warped or bent substrate 50 from one which is unacceptably warped or bent, the first light detection unit 18 and the second light detection unit 19 are configured such that the height or gap of the optical paths 183 and 193 from the upper surface of a flat (un warped or bent) substrate 50 are different from one another. For example, the position of the optical path 183 of the first light detection unit 18 is set to be a position separated from the surface of an unwarped or un-bent substrate 50 by a distance of 200 [μm]. In addition, the position of the optical path 193 of the second light detection unit 19 is set to a position, separated from the surface of the unwarped or un-bent substrate 50, which is further away than the optical path 183 of the first light detection unit 18 is from the unwarped or un-bent substrate 50.

Thus, when the substrate 50 is bent or warped by a small, acceptable, amount, it is possible to detect particles 51 or other defects on the substrate 50 by using the optical path 183 of the first light detection unit 18 which is close to the surface of the substrate 50. In addition, when the substrate 50 is bent or warped, it is possible to detect unacceptable bending of the substrate 50 by using the optical path 183 of the first light detection unit 18 and to detect particles 51 or other defects on the substrate 50 by using the optical path 193 of the second light detection unit 19. In this manner, the substrate processing apparatus 10 can discriminate between an acceptably and unacceptably bent or warped substrate, and determine the presence of particles 51 or other defects on the surface of an acceptably bent or warped substrate 50.

According to the second embodiment, the same operational effects as those in the first embodiment are obtained.

In addition, the substrate processing apparatus 10 includes a plurality of (in this case, two) light detection units 18 and 19, and the height positions of the optical paths 183 and 193 thereof are different from each other. Accordingly, it is possible to detect the particles 51 on the substrate 50 in a state where the bending or warping of the substrate 50 is acceptable. Therefore, the detection accuracy of the particles 51 is improved because particles and other defects on the substrate 50 can be detected despite substrate warpage.

### Modification Example

Meanwhile, in the above-described embodiments, the front chamber 12 may include a load lock chamber (not shown) provided between the front chamber 12 and the transport container 20 in order to move the substrate 50 between a vacuum state in the front chamber and an atmospheric pressure state in the transport container 20. In this case, the mounting unit 131 can move between the processing chamber 11, the front chamber 12, and the load lock chamber. In this case, the substrate processing apparatus 10 includes a mounting unit (not shown), which is capable of moving a substrate 50 between the transport container 20 and the load lock chamber, in addition to the mounting unit 131. The mounting unit (not shown) is configured to receive a substrate 50 in the transport container 20 and transport the substrate 50 into the load lock chamber, and vice-versa.

In the above-described embodiments, the optical path 143 may be moved with respect to the surface of the substrate 50 without simultaneously moving the substrate 50 or the mounting unit 131. Additionally, the mounting unit 131 and the optical path 143 may be simultaneously moved to scan the optical path 143 over the surface of the substrate 50.

A location where the light detection unit 14 is located is not limited to the vicinity of the communication portion 111 within the front chamber 12. For example, the light detection unit 14 may be provided in the vicinity of the communication portion 121.

The optical path 143 of the light detection unit 14 is not limited to being oriented at a right angle with respect to the movement direction of the substrate 50. That is, the optical path 143 may be configured to be non-perpendicular, and non-parallel to, the movement direction of the substrate 50. In addition, the light detection unit 14 may be provided within the processing chamber 11.

In addition, a configuration may be provided in which any one or all of the mounting unit 131 and the light detection units 14, 18, and 19 may be movable in a vertical direction, that is, a direction perpendicular to the surface of the substrate 50. In that case, the control unit 15 can acquire information on the bent or warped condition of the substrate 50 from the previous process and can determine the appropriate position of the mounting unit 131 or the light detection unit 14, 18, or 19 based on the information. Accordingly, it is possible to set a distance between each of the optical paths 143, 183, and 193 and the surface of the substrate 50 which is suitable for the actual state of bending or warping of the substrate 50. As a result, it is possible to achieve an improvement in the detection accuracy of particles 51 or other defect projecting from the surface of the substrate 50.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the disclosure and appended claims.

What is claimed is:

1. A substrate processing apparatus comprising:
a mounting unit on which a substrate is mounted;
alight generating and detection unit that forms an optical path parallel to a surface of the substrate at a location separated from the surface of the substrate by a predetermined distance and is capable of detecting shielding of the optical path; and
a control unit that controls movement of at least one of the mounting unit and the optical path to control relative movement between the optical path and the substrate in a state where parallelism between the optical path and the surface of the substrate is maintained.

2. The substrate processing apparatus according to claim 1, further comprising:
a processing chamber that accommodates the substrate when processing is performed on the substrate; and
a transfer chamber configured to allow transfer of the substrate therethrough between a container accommodating the substrate and the processing chamber,
wherein the light generating and detection unit is provided in the transfer chamber.

3. The substrate processing apparatus according to claim 2, wherein the mounting unit is movable between the processing chamber, the transfer chamber, and the container.

4. The substrate processing apparatus according to claim 3, wherein
when the light generating and detection unit detects shielding of the optical path, the control unit controls movement of the mounting unit so that the substrate is not thereafter placed in the container if a defect or excess warpage of the substrate is detected.

5. The substrate processing apparatus according to claim 3, further comprising:
a notification device configured to provide notification when the light generating and detection unit detects shielding of the optical path.

6. The substrate processing apparatus according to claim 2, further comprising:
a notification device configured to provide notification when the light generating and detection unit detects shielding of the optical path.

7. The substrate processing apparatus according to claim 1, further comprising:
a notification device configured to provide a notification when the light detection unit detects shielding of the optical path.

8. The substrate processing apparatus according to claim 1, further comprising:
a processing chamber that accommodates the substrate when processing is performed on the substrate; and
a transfer chamber configured to allow transfer of the substrate therethrough between a container accommodating the substrate and the processing chamber,
wherein the mounting unit is movable between the processing chamber, the transfer chamber, and the container, and
wherein when the light generating and detection unit detects shielding of the optical path, the control unit controls movement of the mounting unit so that the substrate is not thereafter placed in the container if a defect or excess warpage of the substrate is detected.

9. The substrate processing apparatus according to claim 1, further comprising:
a plurality of the light generating and detection units, each light generating and detecting unit including an optical path,
wherein the optical paths of the plurality of light generating and detection units are separated from the surface of the substrate by different distances.

10. The substrate processing apparatus according to claim 1, wherein the control unit determines that the substrate is warped when the optical path is continuously shielded for a predetermined time period or longer during relative motion of the substrate and the optical path, and determines that defects are present on the surface of the substrate when the optical path is continuously shielded for a period less than the predetermined time period.

11. The substrate processing apparatus of claim 1, further comprising a load lock chamber disposed intermediate of, and in communication with, the transfer chamber and the container.

12. An apparatus for detecting the presence of defects on a wafer, comprising:
a process chamber in which a substrate is processed;
a transfer chamber coupled to the process chamber, the transfer chamber including a container side opening configured to allow receipt and removal of substrates therethrough, and a process side opening configured to allow receipt and removal of substrates therethrough;
a moveable member configured to support a substrate thereon and move the substrate through the container side port, through the transfer chamber, and into the process chamber, and move the substrate from the process chamber to the transfer chamber; and
a light generation and detection unit forming a first optical path, wherein the light generation and detection unit is configured to extend the first optical path in a direction non-parallel to the direction of substrate travel on the moveable member, and the first optical path is disposed parallel to, and spaced from, the upper surface of the substrate.

13. The apparatus of claim 12, wherein the diameter D of the optical path, and the distance H between the substrate upper surface and the optical path, meet the conditions:
D≦100 [μm]; and
H−D/2≧10 [μm]
where H is chosen as the acceptable diameter of a particle on the surface of the substrate.

14. The apparatus of claim 12, further comprising a second optical path, the second optical path extending in a direction non-parallel to the direction of substrate travel on the moveable member, and the second optical path is disposed parallel to, and spaced from the upper surface of the substrate by a greater distance than that between the first optical path and the upper surface of the substrate.

15. A method of determining the presence of defects and warpage of a substrate; comprising:
processing the substrate in a process chamber;
moving the substrate from the process chamber into a transfer chamber coupled to the process chamber on a moveable member; and
providing relative movement between the substrate on the moveable member and the first optical path, wherein the first optical path extends in a direction non-parallel to the direction of substrate travel on the moveable member, and the first optical path is disposed parallel to, and spaced from, the upper surface of the substrate by a distance equal to the acceptable size of a particle on the substrate.

16. The method of claim 15, further comprising:
monitoring the optical path for interruption during a time period in which relative movement between the substrate and optical path is provided; and
determining the condition of the substrate based on the time period over which the optical path is interrupted.
